(19) United States
(12) Patent Application Publication
(10) Pub. No.: US 2024/0315121 A1
(43) Pub. Date: Sep. 19, 2024

(54) MASK AND METHOD OF MANUFACTURING DISPLAY PANEL USING THE SAME

(71) Applicant: Samsung Display Co., Ltd., Yongin-si (KR)

(72) Inventor: NAMJIN KIM, Yongin-si (KR)

(21) Appl. No.: 18/493,753

(22) Filed: Oct. 24, 2023

(30) Foreign Application Priority Data
Mar. 17, 2023 (KR) 10-2023-0035428

(51) Int. Cl. H10K 71/16; C23C 14/04

(52) U.S. Cl. CPC H10K 71/166; C23C 14/042

(57) ABSTRACT

A mask includes: a first portion; and a second portion surrounding the first portion, and having a size smaller than a size of the first portion in a plan view, the second portion including: first blocking portions; and first openings alternately located with the first blocking portions along one direction in a plan view.

### CROSS-REFERENCED TO RELATED APPLICATION

This application claims priority to and the benefit of Korean Patent Application No. 10-2023-0035428, filed on Mar. 17, 2023, in the Korean Intellectual Property Office, the entire content of which is incorporated by reference herein.

### BACKGROUND

### 1. Field

Aspects of embodiments of the present disclosure relate to a mask, and a method of manufacturing a display panel using the mask.

### 2. Description of Related Art

Display devices, such as a television set, a mobile phone, a tablet computer, a navigation unit, a game unit, and the like, provide images to a user, and include a display panel to generate and display the images. The display panel includes an inorganic layer and an organic layer to encapsulate a light emitting element.

### SUMMARY

When the organic layer of the display panel is formed by curing a liquid organic material having fluidity, a reflow phenomenon may (e.g., is likely to) occur by the liquid organic material flowing over dams on the display panel and reaching the end of a cell during a curing process. In this case, an ashing process may be used to remove a portion of the organic layer formed by the reflow phenomenon. However, gases containing oxygen and/or the like may be generated in the organic material during the ashing process, and an electrode of the light emitting element may be oxidized by the gases, resulting in dark spots on the display panel.

One or more embodiments of the present disclosure are directed to a mask for a pretreatment process that is capable of controlling the spread of organic materials during a manufacturing process of a display panel.

One or more embodiments of the present disclosure are directed to a method of manufacturing the display panel using the mask.

According to one or more embodiments of the present disclosure, a mask includes: a first portion; and a second portion surrounding the first portion, and having a size smaller than a size of the first portion in a plan view, the second portion including: first blocking portions; and first openings alternately located with the first blocking portions along one direction in a plan view.

In an embodiment, the first portion may include: a mask hole; and a first area surrounding the mask hole in a plan view, and including second openings located around the mask hole in a plan view.

In an embodiment, each of the first openings may have a polygonal shape.

In an embodiment, each of the first openings may have a circular shape.

In an embodiment, the first openings may have the same size as each other.

According to one or more embodiments of the present disclosure, a method of manufacturing a display panel, includes: providing a preliminary display panel including a display area, a peripheral area adjacent to the display area, and a light emitting element located in the display area; forming a first inorganic layer on the light emitting element to overlap with the display area and the peripheral area; pretreating at least a portion of the first inorganic layer overlapping with the peripheral area through a plasma process using a first mask, the first mask including: a first portion overlapping with the display area; and a second portion spaced from the display area, and overlapping with the peripheral area, the second portion including: first blocking portions; and first openings alternately located with the first blocking portions along one direction in a plan view; and forming an organic layer on the first inorganic layer.

In an embodiment, the first inorganic layer may be formed on the light emitting element using a second mask including a mask opening overlapping with the display area and having a size greater than that of the first openings, and the first inorganic layer may be deposited to correspond to the mask opening.

In an embodiment, a gas containing nitrogen may be used in the plasma process.

In an embodiment, a surface of the first inorganic layer that is pretreated in areas overlapping with the first openings may have a hydrophobicity higher than a hydrophobicity of the surface of the first inorganic layer overlapping with the first portion.

In an embodiment, the method may further include treating a surface of the organic layer through a plasma process using a hydrogen gas.

In an embodiment, the method may further include forming a second inorganic layer on the organic layer.

In an embodiment, the forming of the second inorganic layer may include: forming a first sub-inorganic layer using a first power; and forming a second sub-inorganic layer on the first sub-inorganic layer using a second power higher than the first power.

In an embodiment, the preliminary display panel may be further provided with a module hole defined therethrough to overlap with the display area, and a hole area defined therein to surround the module hole. The first portion may be provided with a mask hole defined therethrough, and a first area surrounding the mask hole in a plan view. The first area may include second openings located around the mask hole in a plan view.

According to one or more embodiments of the present disclosure, a method of manufacturing a display panel, includes: providing a preliminary display panel including a display area, a peripheral area adjacent to the display area, and a light emitting element located in the display area; forming a first inorganic layer on the light emitting element to overlap with the display area and the peripheral area; forming a first layer on the first inorganic layer overlapping with the peripheral area using a first mask to pretreat the first inorganic layer, the first mask including: a first portion overlapping with the display area; and a second portion spaced from the display area and overlapping with the peripheral area, the second portion including: first blocking portions; and first openings alternately located with the first blocking portions along one direction in a plan view; and forming an organic layer on the first inorganic layer. The first layer is deposited corresponding to the first openings.

In an embodiment, a surface of the first layer may have a nitrogen atom content higher than a nitrogen atom content of a surface of the first inorganic layer.

In an embodiment, the first layer may include silicon nitride.

In an embodiment, the method may further include forming a second inorganic layer on the organic layer.

In an embodiment, the method may further include: forming a first sub-inorganic layer on the organic layer using a first power; and forming a second sub-inorganic layer on the first sub-inorganic layer using a second power higher than the first power.

In an embodiment, the first layer may include a hydrophobic material.

In an embodiment, the preliminary display panel may be further provided with a module hole defined therethrough to overlap with the display area, and a hole area defined therein to surround the module hole. The first portion may be provided with a mask hole defined therethrough, and a first area surrounding the mask hole in a plan view. The first area may include second blocking portions, and second openings alternately located with the second blocking portions along one direction in a plan view.

According to one or more embodiments of the present disclosure, the inorganic layer disposed under the organic layer is pretreated, and thus, the spread of the organic layer to the outside of the display panel on the inorganic layer is controlled. Accordingly, the area where the organic layer is formed may be easily controlled.

According to one or more embodiments of the present disclosure, an ashing process to remove the organic layer on the peripheral area is not required, and thus, a process time may be decreased and process costs may be reduced.

According to one or more embodiments of the present disclosure, because the ashing process is not required, the generation of gases, such as oxygen, from the organic layer may be prevented or substantially prevented, the oxidation of an electrode of the light emitting element caused by the gases may be prevented or substantially prevented, and the occurrence of dark spots in the display panel may be prevented or substantially prevented. Accordingly, reliability of the display panel may be improved.

### BRIEF DESCRIPTION OF THE DRAWINGS

The above and other aspects and features of the present disclosure will be more clearly understood from the following detailed description of the illustrative, non-limiting embodiments with reference to the accompanying drawings, wherein:

FIG. 1 is a perspective view of a display device according to an embodiment of the present disclosure;

FIG. 2 is an exploded perspective view of a display device according to an embodiment of the present disclosure;

FIG. 3 is a cross-sectional view of a portion of a display panel according to an embodiment of the present disclosure;

FIG. 4 is a cross-sectional view of a portion of a display panel according to an embodiment of the present disclosure;

FIGS. 5A and 5B are flowcharts of a method of manufacturing a display panel according to embodiments of the present disclosure;

FIG. 6 is a plan view of a process of a manufacturing method of a display panel according to an embodiment of the present disclosure;

FIG. 7 is a perspective view of a process of a manufacturing method of a display panel according to an embodiment of the present disclosure;

FIG. 8A is a plan view of a mask according to an embodiment of the present disclosure;

FIG. 8B is a perspective view of a mask according to an embodiment of the present disclosure;

FIG. 9A is a plan view of a mask according to an embodiment of the present disclosure;

FIG. 9B is a perspective view of a mask according to an embodiment of the present disclosure;

FIG. 10A is a plan view of a mask according to an embodiment of the present disclosure;

FIG. 10B is a perspective view of a mask according to an embodiment of the present disclosure;

FIG. 11 is a plan view of a process of a manufacturing method of a display panel according to an embodiment of the present disclosure;

FIG. 12 is a plan view of a process of a manufacturing method of a display panel according to an embodiment of the present disclosure;

FIG. 13 is a plan view of a process of a manufacturing method of a display panel according to an embodiment of the present disclosure;

FIG. 14 is a plan view of a process of a manufacturing method of a display panel according to an embodiment of the present disclosure; and

FIG. 15 is a plan view of a process of a manufacturing method of a display panel according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

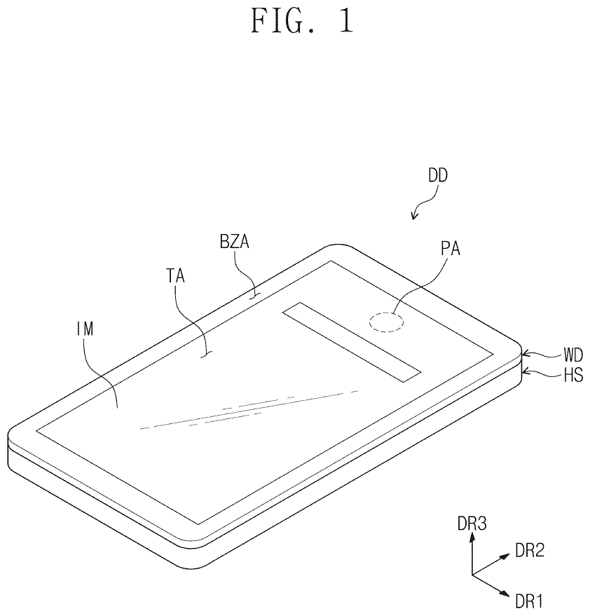

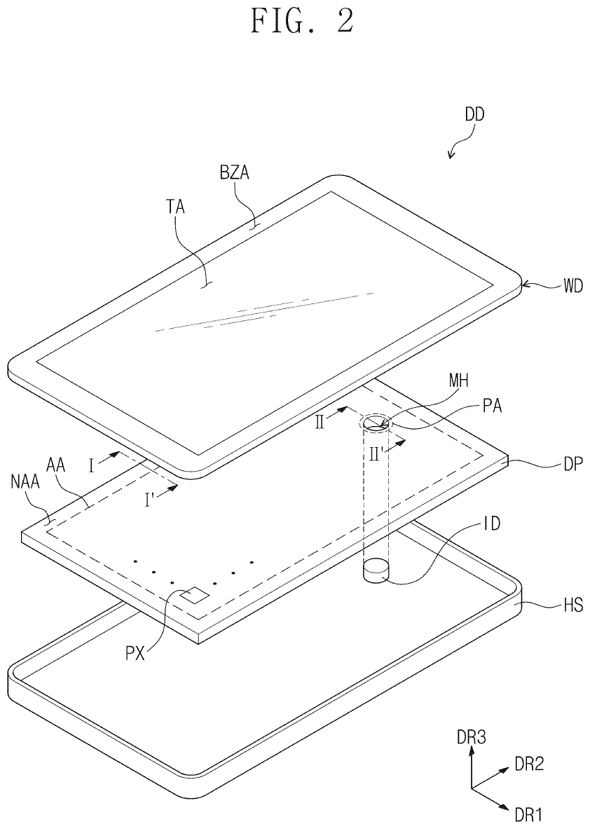

FIG. 1 is a perspective view of a display device DD according to an embodiment of the present disclosure. FIG. 2 is an exploded perspective view of the display device DD according to an embodiment of the present disclosure.

The display device DD may be activated in response to electrical signals. The display device DD may include various embodiments. As an example, the display device DD may be applied to a large-sized display device, such as a television set or an outdoor billboard, or a small and medium-sized display device, such as a mobile phone, a tablet computer, a navigation unit (e.g., a navigation console), and a game unit (e.g., a game console). However, these are merely examples, and the display device DD may be employed in other suitable electronic devices. For convenience, a mobile phone will be described in more detail as a representative example of the display device DD.

The display device DD according to one or more embodiments of the present disclosure may be flexible. The term “flexible” used herein refers to the property of being able to be bent from a structure that is completely bent to a structure that is bent at a scale of a few nanometers. For example, the flexible display device DD may be a curved display device or a foldable display device. According to an embodiment, the display device DD may be rigid.

The display device DD may include a display surface to display an image IM through a front surface thereof. The display device DD may display the image IM through the display surface toward a third direction DR3, which is parallel to or substantially parallel to a plane defined by a first direction DR1 and a second direction DR2. The third direction DR3 may cross (e.g., may intersect) each of the first and second directions DR1 and DR2, and may be parallel to or substantially parallel to a normal line direction of the display surface. The image IM displayed through the display surface may include a still image as well as a video.

Front (or upper) and rear (or lower) surfaces of each member of the display device DD may be defined with respect to a direction in which the image IM is displayed. The front surface and the rear surface may be opposite to each other in the third direction DR3. Meanwhile, the directions indicated by the first, second, and third directions DR1, DR2, and DR3 may be relative to each other, and thus, the directions indicated by the first, second, and third directions DR1, DR2, and DR3 may be variously modified to other suitable directions.

The display device DD may include a window member WD, a display panel DP, an electronic module (e.g., an electronic sensor, circuit, or device) ID, and a housing member HS.

The window member WD may be disposed on the display panel DP. The window member WD may protect the display panel DP from external impacts and/or scratches.

The window member WD may include an optically transparent material. For example, the window member WD may include a glass substrate, a sapphire substrate, or a plastic film. The window member WD may have a single-layer or multi-layered structure. As an example, the window member WD having the multi-layered structure may include a plurality of plastic films coupled to each other by an adhesive, or a glass substrate and a plastic film coupled to the glass substrate by an adhesive.

A front surface of the window member WD may correspond to the front surface of the display device DD. The front surface of the window member WD may include a transmissive area TA and a bezel area BZA.

The transmissive area TA may have a relatively high light transmittance in the front surface of the window member WD. A user may view the image IM provided from the display panel DP through the transmissive area TA.

The transmissive area TA may have a quadrangular shape parallel to each of the first and second directions DR1 and DR2, however, the present disclosure is not limited thereto. The transmissive area TA may have various suitable shapes, and should not be particularly limited.

The bezel area BZA may be defined to be adjacent to the transmissive area TA. As an example, the bezel area BZA may surround (e.g., around a periphery of) the transmissive area TA. The bezel area BZA may be an area having a relatively lower light transmittance as compared with the transmissive area TA. The bezel area BZA may be an area on which a material having a suitable color (e.g., a predetermined color) is printed or coated. The bezel area BZA may prevent or substantially prevent reflection of a light, so components of the display panel DP disposed overlapping with the bezel area BZA may be prevented or substantially prevented from being viewed from the outside.

The display panel DP may be disposed between the window member WD and the housing member HS. The display panel DP may display the image IM in response to electrical signals. The display panel DP may be a light emitting kind of display panel, but is not limited thereto. As an example, the display panel DP may be an organic light emitting display panel, an inorganic light emitting display panel, or a quantum dot light emitting display panel.

The display panel DP may include a display area AA and a peripheral area NAA. The display panel DP may include pixels PX disposed in the display area AA. Each of the pixels PX may include a light emitting element, and a pixel driving circuit electrically connected to the light emitting element. The pixels PX may emit light in response to electrical signals, and thus, the image IM may be displayed in the display area AA. The display area AA may overlap with the transmissive area TA. The image IM displayed in the display area AA may be provided to the outside through the transmissive area TA.

The peripheral area NAA may be defined to be adjacent to the display area AA. As an example, the peripheral area NAA may surround (e.g., around a periphery of) the display area AA when viewed in the plane (e.g., in a plan view). A driving circuit or a driving line may be disposed in the peripheral area NAA to drive the pixels PX arranged in the display area AA. The peripheral area NAA may overlap with the bezel area BZA. Due to the bezel area BZA, components of the display panel DP, which are disposed in the peripheral area NAA, may be prevented or substantially prevented from being viewed from the outside.

The display panel DP may include a hole area PA defined in the display area AA. The hole area PA may be an area in which a module hole MH defined through (e.g., penetrating) the display panel DP is formed. The hole area PA may be surrounded (e.g., around a periphery thereof) by the display area AA when viewed in the plane (e.g., in a plan view), but the present disclosure is not limited thereto or thereby. A portion of the hole area PA may be surrounded (e.g., around a periphery thereof) by the display area AA, and another portion of the hole area PA may be surrounded (e.g., around a periphery thereof) by the peripheral area NAA. According to an embodiment, the hole area PA may be defined in the peripheral area NAA.

The module hole MH may be defined through (e.g., may penetrate) at least one component overlapping with the hole area PA from among the components of the display panel DP. FIG. 2 shows one module hole MH, however, the module hole MH may be provided in a plurality. The module holes MH may be defined in one hole area PA, or may be respectively defined in a plurality of hole areas PA.

The electronic module ID may be an electronic component that outputs or receives an optical signal. As an example, the electronic module ID may be a camera that takes a picture of an external object, a proximity sensor that recognizes an object approaching thereto using an optical signal, or an infrared light emission sensor that emits light.

The electronic module ID may be disposed under the display panel DP. At least a portion of the electronic module ID may overlap with the module hole MH. The electronic module ID may transmit or receive an optical signal through the module hole MH. Because the module hole MH is formed through (e.g., penetrates) the display panel DP, the area where the module hole MH is formed may have a light transmittance higher than that of the area where the pixels PX are arranged in the display area AA. Accordingly, the electronic module ID overlapping with the module hole MH may easily receive or output the optical signal.

The housing member HS may be disposed under the display panel DP. The housing member HS may define a rear surface of the display device DD. The housing member HS may be coupled to the window member WD to form an exterior of the display device DD. The housing member HS may be coupled to the window member WD to define an inner space therein, and the components of the display device DD, such as the display panel DP, the electronic module ID, and the like, may be accommodated in the inner space.

The housing member HS may include a material having a relatively high rigidity. As an example, the housing member HS may include a plurality of frames and/or plates formed of glass, plastic, or a metal material, or various suitable combinations thereof. The housing member HS may protect the components accommodated in the inner space from external impacts. The housing member HS may absorb the external impacts applied to the display panel DP from the outside, or may prevent or substantially prevent a foreign substance and moisture from entering the display panel DP.

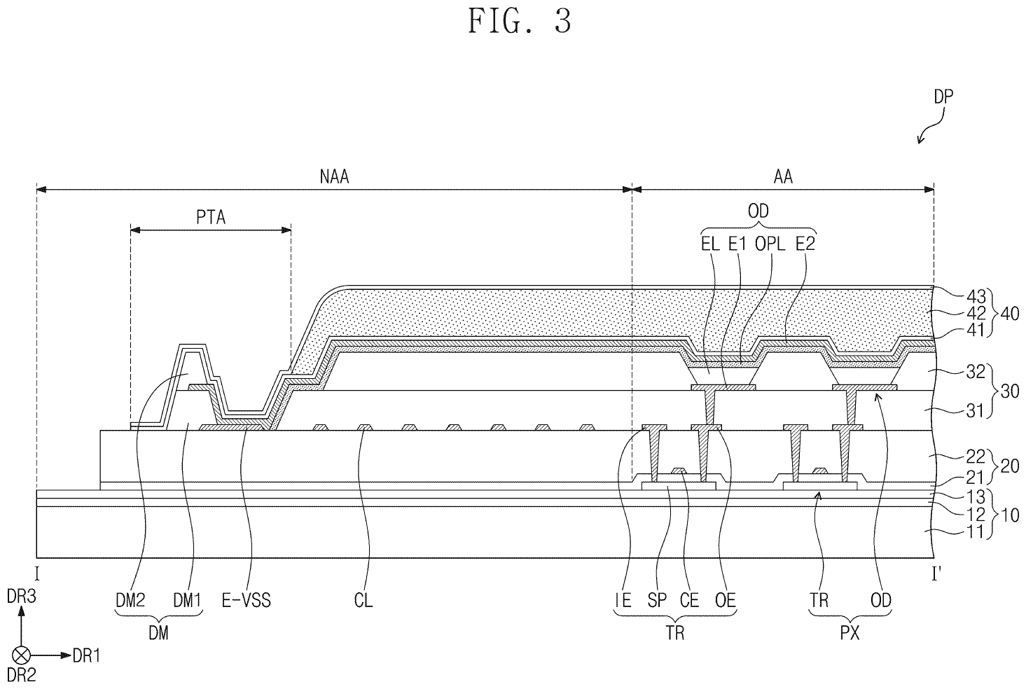

FIG. 3 is a cross-sectional view of a portion of the display panel DP according to an embodiment of the present disclosure, and may be a view taken along the line I-I′ of FIG. 2. FIG. 3 shows a cross-section of the display panel DP in the peripheral area NAA, and a portion of the display area AA adjacent to the peripheral area NAA.

Referring to FIG. 3, the display panel DP may include an insulating substrate 10, a pixel PX, a plurality of driving signal lines CL, a power connection pattern E-VSS, a dam portion DM, and a plurality of insulating layers 20, 30, and 40. The insulating layers 20, 30, and 40 may include a circuit insulating layer 20, a display insulating layer 30, and an encapsulation layer 40.

The insulating substrate 10 may define a base surface on which the pixel PX is disposed. The insulating substrate 10 may include a base layer 11, a first auxiliary layer 12, and a second auxiliary layer 13.

The base layer 11 may include an insulating material. The base layer 11 may be a flexible layer, but the present disclosure is not limited thereto or thereby, and the base layer 11 may be a rigid layer. As an example, the base layer 11 may include a polymer, such as polyimide (PI), or a glass material, but the material for the base layer 11 is not limited thereto or thereby.

The first auxiliary layer 12 and the second auxiliary layer 13 may be disposed on the base layer 11. The first auxiliary layer 12 and the second auxiliary layer 13 may entirely cover the base layer 11.

The first auxiliary layer 12 may include a barrier layer. Accordingly, the first auxiliary layer 12 may prevent or substantially prevent oxygen and/or moisture from entering the pixel PX through the base layer 11.

The second auxiliary layer 13 may include a buffer layer. Accordingly, the second auxiliary layer 13 may control a surface energy of the insulating substrate 10 to allow the pixel PX to be stably disposed on the insulating substrate 10.

However, the present disclosure is not limited thereto or thereby, and a stacking order of the first auxiliary layer 12 and the second auxiliary layer 13 may be variously modified, or one of the first auxiliary layer 12 or the second auxiliary layer 13 may be omitted as needed or desired. According to an embodiment, at least one of the base layer 11, the first auxiliary layer 12, or the second auxiliary layer 13 may be provided in a plurality, and may be alternately stacked with the others.

The pixel PX may be disposed on the insulating substrate 10. As described above, the pixel PX may be disposed in the display area AA of the insulating substrate 10.

The pixel PX may include a plurality of thin film transistors (e.g., a driving transistor and a switching transistor), a capacitor, and a light emitting element OD. The pixel PX may be electrically connected to signal lines of the display panel DP. FIG. 3 shows a thin film transistor TR and a light emitting element OD from among the components of the pixel PX as a representative example.

The thin film transistor TR may be disposed on the insulating substrate 10. The thin film transistor TR may form a thin film transistor layer with the circuit insulating layer 20. The thin film transistor TR may include a semiconductor pattern SP, a control electrode CE, an input electrode IE, and an output electrode OE. The circuit insulating layer 20 may include a first insulating layer 21 and a second insulating layer 22, which are sequentially stacked on the insulating substrate 10.

The semiconductor pattern SP may be disposed on the insulating substrate 10. The semiconductor pattern SP may include one or more semiconductor materials, such as crystalline silicon, amorphous silicon, or one or more metal oxides. The semiconductor pattern SP may include source and drain areas with a relatively higher conductivity, and a channel area with a relatively lower conductivity. The source area and the drain area may be spaced apart from each other with the channel area interposed therebetween.

The control electrode CE may be disposed over (e.g., on) the first insulating layer 21 to overlap with the semiconductor pattern SP. The control electrode CE may be spaced apart from the semiconductor pattern SP with the first insulating layer 21 interposed therebetween. However, the present disclosure is not limited thereto or thereby, and the control electrode CE may be disposed under the semiconductor pattern SP.

The input electrode IE and the output electrode OE may be disposed over (e.g., on) the second insulating layer 22. The input electrode IE and the output electrode OE may be spaced apart from the control electrode CE with the second insulating layer 22 interposed therebetween. The input electrode IE and the output electrode OE of the thin film transistor TR may be connected to areas of the semiconductor pattern SP, respectively, which have the higher conductivity, after penetrating the first insulating layer 21 and the second insulating layer 22. However, the structure of the thin film transistor TR is not limited thereto or thereby. According to an embodiment, the input electrode IE and the output electrode OE may be disposed under the semiconductor pattern SP, or may be disposed at (e.g., in or on) the same layer as that of the semiconductor pattern SP to be directly connected to the semiconductor pattern SP. The thin film transistor TR may have a variety of suitable structures, and the present disclosure is not limited to any one particular structure.

The light emitting element OD may be disposed on the circuit insulating layer 20. The light emitting element OD may form a display element layer together with the display insulating layer 30. The light emitting element OD may include a first electrode E1, a light emitting layer EL, a control layer OPL, and a second electrode E2. The display insulating layer 30 may include a third insulating layer 31 and a fourth insulating layer 32, which are sequentially stacked.

The first electrode E1 may be connected to the thin film transistor TR after penetrating the third insulating layer 31, however, the present disclosure is not limited thereto or thereby. According to an embodiment, the display panel DP may further include a separate connection electrode disposed between the first electrode E1 and the thin film transistor TR. In this case, the first electrode E1 may be electrically connected to the thin film transistor TR by the connection electrode.

The fourth insulating layer 32 may be disposed on the third insulating layer 31. A light emitting opening may be defined through the fourth insulating layer 32. The light emitting opening may expose at least a portion of the first electrode E1. The fourth insulating layer 32 may be a pixel definition layer that defines an area where the light emitting element OD emits light.

The light emitting layer EL may be disposed in the light emitting opening, and may be disposed on the first electrode E1 exposed through the light emitting opening. The light emitting layer EL may include a light emitting material. As an example, the light emitting layer EL may include at least one material from among various suitable materials for respectively emitting red, green, and blue light. The light emitting layer EL may include a fluorescent material or a phosphorescent material. The light emitting layer EL may include an organic material and/or an inorganic material. The light emitting layer EL may emit light in response to a difference in an electric potential between the first electrode E1 and the second electrode E2.

The control layer OPL may be disposed between the first electrode E1 and the second electrode E2. The control layer OPL may be disposed adjacent to the light emitting layer EL. In the present embodiment, the control layer OPL is shown as being disposed between the light emitting layer EL and the second electrode E2, but the present disclosure is not limited thereto or thereby. According to an embodiment, the control layer OPL may be disposed between the light emitting layer EL and the first electrode E1. According to an embodiment, the control layer OPL may be provided in a plurality, and the control layers OPL may be stacked in the third direction DR3 with the light emitting layer EL interposed therebetween.

The control layer OPL may be commonly provided in the pixels PX. According to an embodiment, the control layer OPL may have an integral shape extending from the display area AA to the peripheral area NAA, but the present disclosure is not limited thereto or thereby.

The second electrode E2 may be disposed on the light emitting layer EL. The second electrode E2 may be commonly provided in the pixels PX. The second electrode E2 may have an integral shape extending from the display area AA to the peripheral area NAA.

The second electrode E2 may include a transmissive conductive material or a semi-transmissive conductive material. Accordingly, the light generated by the light emitting layer EL may easily travel to the third direction DR3 after passing through the second electrode E2. However, the present disclosure is not limited thereto. According to an embodiment, the light emitting element OD may include the first electrode E1 including the transmissive or semi-transmissive material, and may be operated in a rear surface light emitting manner, or in a both surface light emitting manner in which light is emitted to both of the front and rear surfaces.

The encapsulation layer 40 may be disposed on the light emitting element OD to encapsulate the light emitting element OD. The encapsulation layer 40 may be commonly provided in the pixels PX. In some embodiments, a capping layer may be further disposed between the second electrode E2 and the encapsulation layer 40 to cover the second electrode E2.

The encapsulation layer 40 may include a first inorganic layer 41, an organic layer 42, and a second inorganic layer 43, which are sequentially stacked in the third direction DR3. However, stacking structure of the encapsulation layer 40 is not limited thereto or thereby.

The first inorganic layer 41 may cover the second electrode E2. The first inorganic layer 41 may prevent or substantially prevent external moisture and/or oxygen from entering the light emitting element OD. For example, the first inorganic layer 41 may include silicon nitride, silicon oxide, or a suitable compound thereof. The first inorganic layer 41 may have a single-layer structure of an inorganic layer, or a multi-layered structure in which multiple sub-inorganic layers are stacked in the third direction DR3. The first inorganic layer 41 may be formed by a deposition process using an open mask having a portion corresponding to the display area AA that is opened.

The organic layer 42 may be disposed on the first inorganic layer 41 to contact the first inorganic layer 41. The organic layer 42 may define a flat or substantially flat surface on the first inorganic layer 41. An uneven shape formed on an upper surface of the first inorganic layer 41 and particles existing on the first inorganic layer 41 may be covered by the organic layer 42, and thus, an influence caused by a surface state of the upper surface of the first inorganic layer 41 on components formed on the organic layer 42 may be blocked. In addition, the organic layer 42 may relieve a stress between the layers in contact with the organic layer 42. The organic layer 42 may be formed by a solution process, such as a spin coating process, a slit coating process, or an inkjet process.

The second inorganic layer 43 may be disposed on the organic layer 42 to cover the organic layer 42. Because the second inorganic layer 43 is disposed on the organic layer 42, the second inorganic layer 43 may be stably formed on a relatively flat or substantially flat surface. The second inorganic layer 43 may prevent or substantially prevent moisture and/or oxygen from entering the organic layer 42. The second inorganic layer 43 may include silicon nitride, silicon oxide, or a suitable compound thereof. The second inorganic layer 43 may have a single-layer structure of an inorganic layer, or a multi-layered structure in which multiple sub-inorganic layers are stacked in the third direction DR3. The second inorganic layer 43 may be formed by a deposition process using an open mask having a portion corresponding to the display area AA that is opened.

The driving signal line CL, the dam portion DM, and the power connection pattern E-VSS may be disposed in the peripheral area NAA.

The driving signal line CL may be provided in a plurality, and may be disposed on the circuit insulating layer 20. The driving signal line CL may be a routing line connected to a pad, or a line constituting an integrated circuit IC. As an example, the driving signal line CL may include a power supply line, an initialization voltage line, or a light emitting control line.

The power connection pattern E-VSS may supply a power voltage to the light emitting element OD. The power connection pattern E-VSS may correspond to a power terminal of the pixel PX. The second electrode E2 may extend to the peripheral area NAA, and may be connected to the power connection pattern E-VSS. In the present embodiment, the power voltage supplied to the pixels PX by the power connection pattern E-VSS may be a voltage commonly supplied to the pixels PX.

The dam portion DM may be disposed at a suitable position to cover a portion of the power connection pattern E-VSS, however, the present disclosure is not limited thereto or thereby. According to an embodiment, the dam portion DM may be disposed outside the power connection pattern E-VSS. In the present embodiment, the dam portion DM may have a multi-layered structure including a first dam DM1 and a second dam DM2.

The first dam DM1 may include the same material as that of the third insulating layer 31. The first dam DM1 may be concurrently or substantially simultaneously formed with the third insulating layer 31, and may be disposed at (e.g., in or on) the same layer as that of the third insulating layer 31.

The second dam DM2 may be disposed on the first dam DM1. In the present embodiment, a portion of the second electrode E2 may be inserted (e.g., may be interposed) between the first dam DM1 and the second dam DM2. In other words, the second dam DM2 according to the present embodiment may be formed through a separate process after the second electrode E2 is formed, however, the present disclosure is not limited thereto or thereby. According to an embodiment, the second dam DM2 may be concurrently or substantially simultaneously formed with the fourth insulating layer 32. According to an embodiment, the dam portion DM may have a single-layer structure, but the present disclosure is not limited thereto or thereby.

The first inorganic layer 41 and the second inorganic layer 43 may extend from the display area AA to the outside of the dam portion DM. Accordingly, the dam portion DM may be covered by the first inorganic layer 41 and the second inorganic layer 43. The first inorganic layer 41 and the second inorganic layer 43 may be in contact with each other on the dam portion DM, and the organic layer 42 disposed between the first inorganic layer 41 and the second inorganic layer 43 may be encapsulated. The organic layer 42 may be disposed at an inner side of the dam portion DM, however, the present disclosure is not limited thereto or thereby. According to an embodiment, a portion of the organic layer 42 may extend to an area overlapping with the dam portion DM, and the present disclosure is not limited thereto or thereby.

The dam portion DM may be disposed adjacent to at least one side of the display area AA. The dam portion DM may surround (e.g., around a periphery of) the display area AA when viewed in the plane (e.g., in a plan view). The dam portion DM may prevent or substantially prevent the organic layer 42 from overflowing to the outside of the display panel DP. The organic layer 42 may be formed by coating a liquid organic material on the first inorganic layer 41, and the dam portion DM may prevent or substantially prevent the liquid organic material from overflowing to the outside of the dam portion DM.

The first inorganic layer 41 of the encapsulation layer 40 according to an embodiment of the present disclosure may include a pretreatment area PTA where a pretreatment process described in more detail below is carried out.

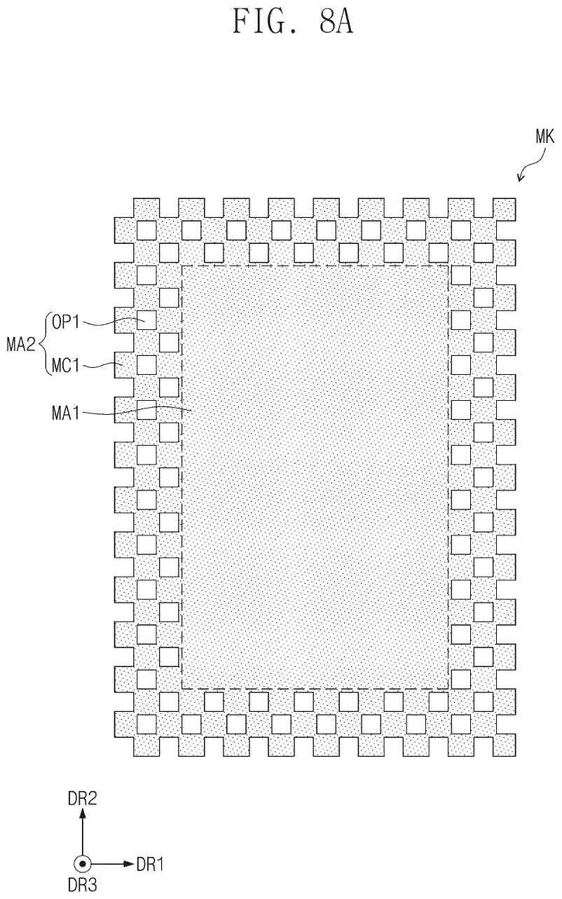

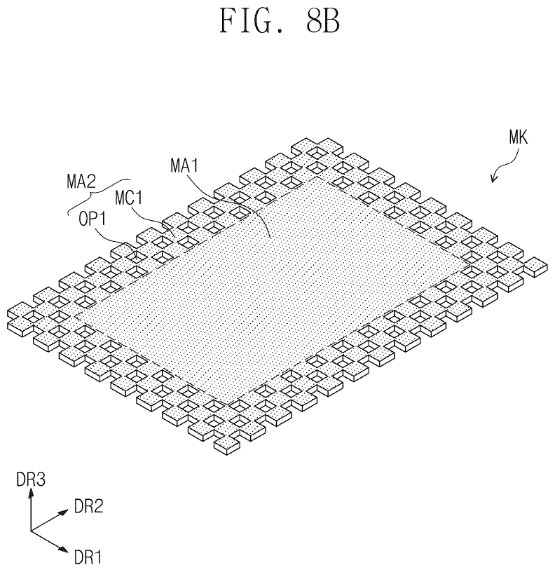

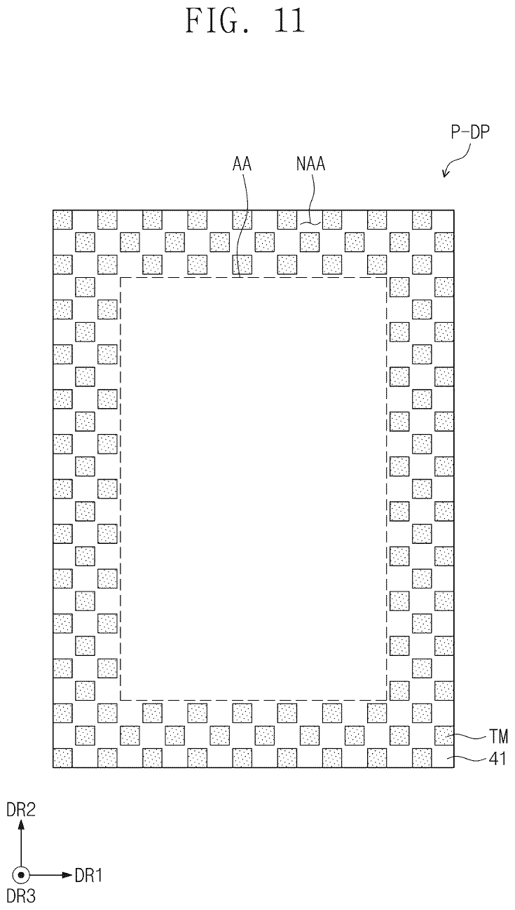

The organic layer 42 may be formed by curing the liquid organic material having fluidity, and a reflow phenomenon in which the liquid organic material flows to an end of a cell over the dam portion DM on the display panel DP during the curing process may occur. To prevent or substantially prevent the occurrence of the reflow phenomenon of the liquid organic material, an upper portion of the first inorganic layer 41 may be pretreated using a mask MK (e.g., refer to FIGS. 8A to 10B) described in more detail below. A pretreatment portion TM (e.g., refer to FIG. 11) described in more detail below may be formed in the first inorganic layer 41 through the pretreatment process for the first inorganic layer 41, and the pretreatment area PTA may include the pretreatment portion TM. The pretreatment portion TM may correspond to an area where a surface of the first inorganic layer 41 is directly (e.g., actually) pretreated within the pretreatment area PTA.

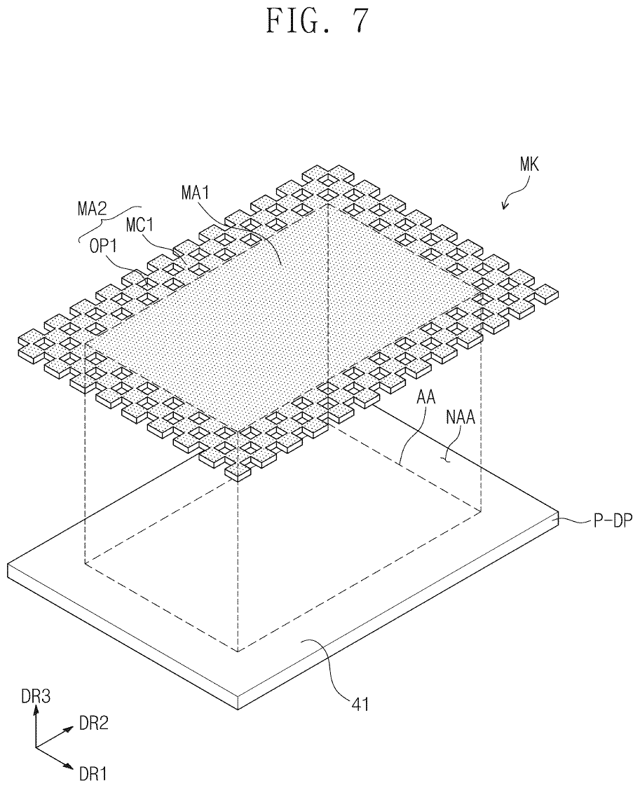

The pretreatment area PTA may correspond to a second portion MA2 (e.g., refer to FIG. 7) of the mask MK in the pretreatment process for the first inorganic layer 41, and may correspond to a portion of the first inorganic layer 41 in which at least a portion is pretreated. The pretreatment area PTA may include an area in which the pretreatment portion TM (e.g., refer to FIG. 11) is formed and an area in which the pretreatment portion TM is not formed, which are alternately arranged in one direction.

The first inorganic layer 41 corresponding to the pretreatment area PTA may have a low interfacial affinity with the organic layer 42 when compared with the first inorganic layer 41 corresponding to the display area AA, due to the pretreatment portion TM (e.g., refer to FIG. 11) having the low interfacial affinity with the organic layer 42. Accordingly, the reflow phenomenon of the organic material may be prevented or substantially prevented in the pretreatment area PTA, and the organic layer 42 may be prevented or substantially prevented from extending to the outside of the peripheral area NAA by the pretreatment area PTA.

When the organic layer 42 is formed, the reflow phenomenon of the organic material may be controlled by the pretreatment area PTA and the dam portion DM. However, in a case where the organic material comes into contact with the pretreatment area PTA before the dam portion DM in the process of forming the organic layer 42, the reflow phenomenon of the organic material may be sufficiently prevented by the pretreatment area PTA, and thus, the dam portion DM may serve an auxiliary role in preventing the reflow phenomenon of the organic material.

The area where the organic layer 42 is formed may be determined by the shape and range of the pretreatment area PTA. The range of the pretreatment area PTA shown in FIG. 3 is illustrated as an example, and the present disclosure is not limited thereto or thereby. FIG. 3 shows a structure in which an edge of the organic layer 42 is aligned with a boundary of the pretreatment area PTA, however, the present disclosure is not limited thereto or thereby. According to an embodiment, a portion of the edge of the organic layer 42 may overlap with or substantially overlap with the pretreatment area PTA depending on positions at which the pretreatment portions TM (e.g., refer to FIG. 11) are formed in the pretreatment area PTA.

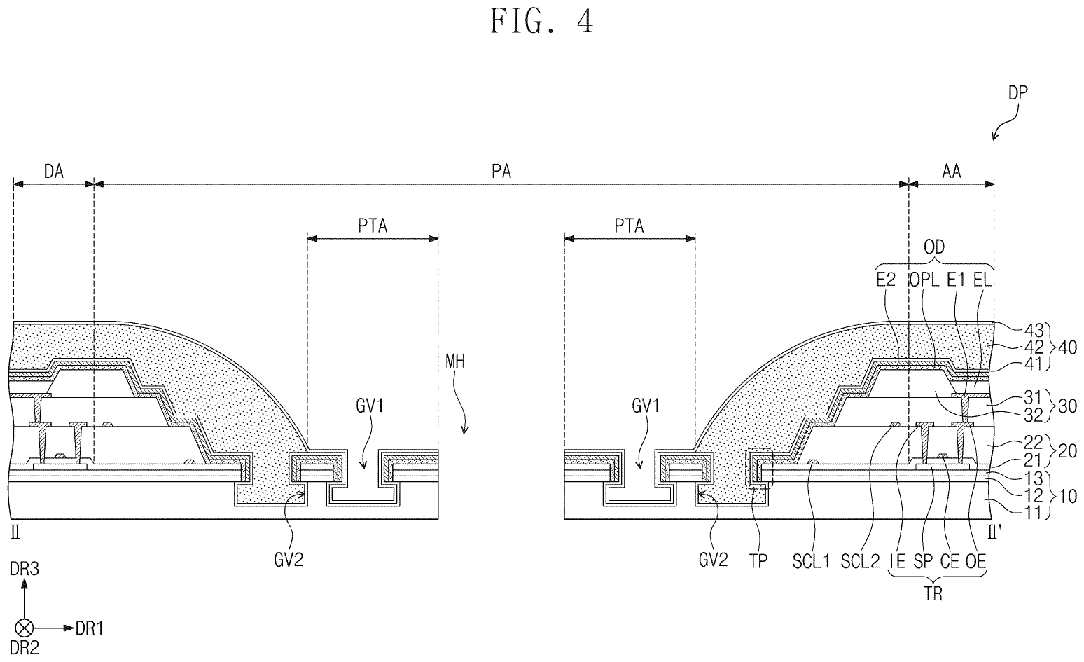

FIG. 4 is a cross-sectional view of a portion of the display panel DP according to an embodiment of the present disclosure, and may be a view taken along the line II-II′ of FIG. 2. FIG. 4 shows a cross-section of the display panel DP in the hole area PA, and a portion of the display area AA adjacent to the hole area PA as a representative example. Hereinafter, redundant description of the same or substantially the same components in FIG. 4 as those described above with reference to FIG. 3 may not be repeated.

Referring to FIG. 4, the display panel DP may include the hole area PA adjacent to the display area AA. The hole area PA may be surrounded (e.g., around a periphery thereof) by the display area AA when viewed in the plane (e.g., in a plan view). The display panel DP may include signal lines SCL1 and SCL2 and groove patterns GV1 and GV2 disposed in the hole area PA. The module hole MH may be defined through (e.g., may penetrate) the display panel DP.

The signal lines SCL1 and SCL2 may include a first signal line SCL1 and a second signal line SCL2, which are disposed at (e.g., in or on) different layers from each other. As an example, the first signal line SCL1 may be disposed on the first insulating layer 21, and the second signal line SCL2 may be disposed on the second insulating layer 22. However, the positions where the signal lines SCL1 and SLC2 are disposed are not limited thereto or thereby.

The signal lines SCL1 and SLC2 may be electrically connected to the pixels PX (e.g., refer to FIG. 3) disposed adjacent to the hole area PA. Accordingly, the pixels PX that are spaced apart from each other around the module hole MH may be electrically connected to each other.

The module hole MH may be spaced apart from the pixels PX (e.g., refer to FIG. 3), and may be disposed in the hole area PA. The module hole MH may be defined in the hole area PA. The module hole MH may be formed through (e.g., may penetrate) the components disposed in the hole area PA from among the components of the display panel DP. As an example, the module hole MH may be formed through (e.g., may penetrate) the insulating substrate 10, the control layer OPL, the second electrode CE, the first inorganic layer 41, and the second inorganic layer 43. However, the components of the display panel DP, which are penetrated to form the module hole MH, are not limited thereto or thereby.

The groove patterns GV1 and GV2 may be disposed between the module hole MH and the display area AA when viewed in the plane (e.g., in a plan view). The groove patterns GV1 and GV2 may be formed by removing portions of some of the components of the display panel DP to be recessed from an upper surface of the display panel DP. Unlike the module hole MH, the groove patterns GV1 and GV2 may not penetrate (e.g., entirely through) the display panel DP. In other words, a rear surface of the insulating substrate 10 may not be opened by the groove patterns GV1 and GV2.

Each of the groove patterns GV1 and GV2 may be formed by penetrating some of the components of the display panel DP, and only a portion of the base layer 11. In the present embodiment, each of the groove patterns GV1 and GV2 may be formed by completely penetrating the first auxiliary layer 12, the second auxiliary layer 13, and the first insulating layer 21, and removing a portion of the base layer 11.

The control layer OPL and the second electrode E2 may be formed after the groove patterns GV1 and GV2 are formed. As an example, the control layer OPL and the second electrode E2 may be formed after portions of the first auxiliary layer 12, the second auxiliary layer 13, and the first insulating layer 21 are removed. The control layer OPL and the second electrode E2 may be formed through a deposition process. Accordingly, the control layer OPL and the second electrode E2 may cover cross-sections of the first auxiliary layer 12, the second auxiliary layer 13, and the first insulating layer 21, which are defined by removing the portions of the first auxiliary layer 12, the second auxiliary layer 13, and the first insulating layer 21.

The first inorganic layer 41 may extend to the hole area PA to cover the groove patterns GV1 and GV2. As an example, the first inorganic layer 41 may cover the second electrode E2 formed on the cross-sections of the first auxiliary layer 12, the second auxiliary layer 13, and the first insulating layer 21, and an inner surface of the base layer 11 that is recessed.

Each of the groove patterns GV1 and GV2 may have an undercut shape with a tip portion TP that protrudes inwardly. As an example, the first auxiliary layer 12, the second auxiliary layer 13, and the first insulating layer 21 may protrude from the base layer 11, and the undercut may be formed between the base layer 11 and the first auxiliary layer 12, the second auxiliary layer 13, and the first insulating layer 21. The first inorganic layer 41 may continuously cover the components disposed thereunder to the protruded tip portion TP. The display panel DP may have various suitable layer structures, as long as the tip portion TP is formed in the groove patterns GV1 and GV2, and is not particularly limited to any one structure.

The groove patterns GV1 and GV2 may include a first groove pattern GV1, and a second groove pattern GV2 disposed to be spaced apart from the first groove pattern GV1. The first groove pattern GV1 may be disposed to be closer to the module hole MH than the second groove pattern GV2. In other words, a distance between the first groove pattern GV1 and the module hole MH may be less than a distance between the second groove pattern GV2 and the module hole MH.

The first groove pattern GV1 and/or the second groove pattern GV2 may be selectively filled with the organic layer 42 extending from the display area AA to the hole area PA. As an example, the first groove pattern GV1 may be exposed without being covered by the organic layer 42, and the second groove pattern GV2 may be filled with the organic layer 42. However, the present disclosure is not limited thereto or thereby, and the groove patterns GV1 and GV2 may be spaced apart from the organic layer 42.

As the organic layer 42 is filled in the second groove pattern GV2, the tip portion TP of the second groove pattern GV2 may be supported. Accordingly, damage to the tip portion TP, which may be caused by the protruded shape of the tip portion TP, may be prevented or substantially prevented, and thus, a durability of the display panel DP may be improved.

However, the first groove pattern GV1 may not be filled with the organic layer 42. The first groove pattern GV1 that is adjacent to the module hole MH may be exposed without being covered by the organic layer 42. Because at least one groove pattern from among the groove patterns GV1 and GV2 may be exposed without being covered by the organic layer 42, a continuity of the organic layer 42 in the hole area PA may be interrupted. Accordingly, a path of external contaminants that may infiltrate into the hole area PA via the module hole MH may be blocked from entering the display area AA through the organic layer 42.

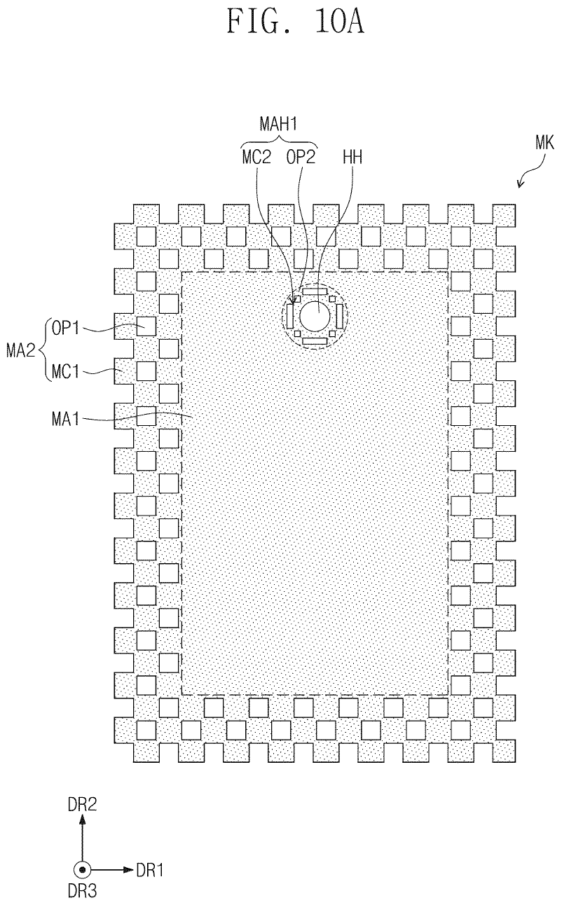

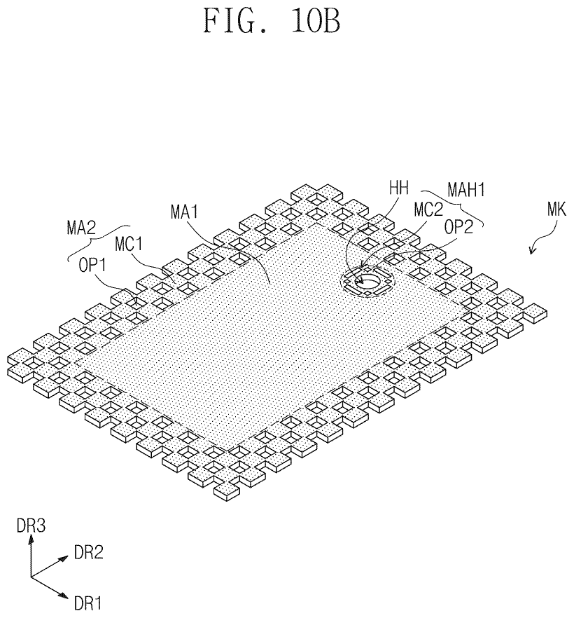

The organic layer 42 may be formed by curing the liquid organic material having fluidity, and the liquid organic material may be filled in the first groove pattern GV1 of the display panel and may flow to the module hole MH during the curing process. In this case, the continuity of the organic layer 42 in the hole area PA may not be blocked. According to one or more embodiments of the present disclosure, the upper portion of the first inorganic layer 41 may be pretreated using a mask MK (e.g., refer to FIGS. 10A and 10B) described in more detail below to prevent or substantially prevent the defect from occurring.

The first inorganic layer 41 of the encapsulation layer 40 may include the pretreatment area PTA overlapping with the hole area PA. As an example, the pretreatment area PTA overlapping with the hole area PA may surround (e.g., around a periphery of) the module hole MH when viewed in the plane (e.g., in a plan view), however, the present disclosure is not limited thereto or thereby.

The pretreatment area PTA may correspond to a first area MAH1 (e.g., refer to FIG. 10A) of the mask MK in the pretreatment process for the first inorganic layer 41, and may correspond to a portion of the first inorganic layer 41 in which at least a portion is pretreated. Areas in which the pretreatment portion is formed to correspond to second openings OP2 (e.g., refer to FIG. 10A) may be arranged along the module hole MH in the pretreatment area PTA.

The first inorganic layer 41 corresponding to the pretreatment area PTA may have a low interfacial affinity with the organic layer 42 when compared with the first inorganic layer 41 corresponding to display area AA, due to the pretreatment portion having the low interfacial affinity with the organic layer 42. Accordingly, the reflow phenomenon of the organic material may be prevented or substantially prevented in the pretreatment area PTA, and the organic layer 42 may be prevented from extending to the module hole MH in the hole area PA.

The area where the organic layer 42 is formed may be determined by the shape and range of the pretreatment area PTA. The range of the pretreatment area PTA shown in FIG. 4 is illustrated as an example, and the present disclosure is not limited thereto or thereby. FIG. 4 shows a structure in which an edge of the organic layer 42 is aligned with a boundary of the pretreatment area PTA, however, the present disclosure is not limited thereto or thereby. According to an embodiment, a portion of the edge of the organic layer 42 may overlap with or substantially overlap with the pretreatment area PTA depending on positions at which the pretreatment portions are formed in the pretreatment area PTA.

The mask MK (e.g., refer to FIG. 7) may be used in the manufacturing process of the display panel DP. The first inorganic layer 41 corresponding to the pretreatment area PTA may be pretreated by the mask MK (e.g., refer to FIG. 7). Hereinafter, the mask MK and the manufacturing process of the display panel DP using the mask MK will be described in more detail.

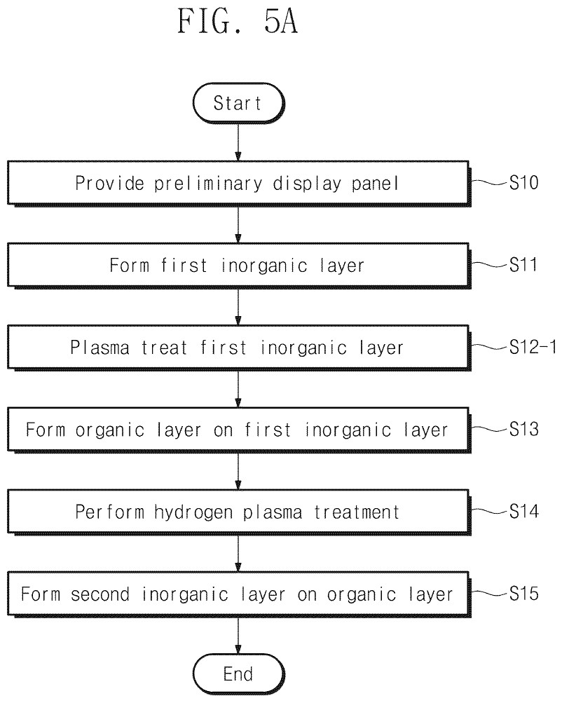

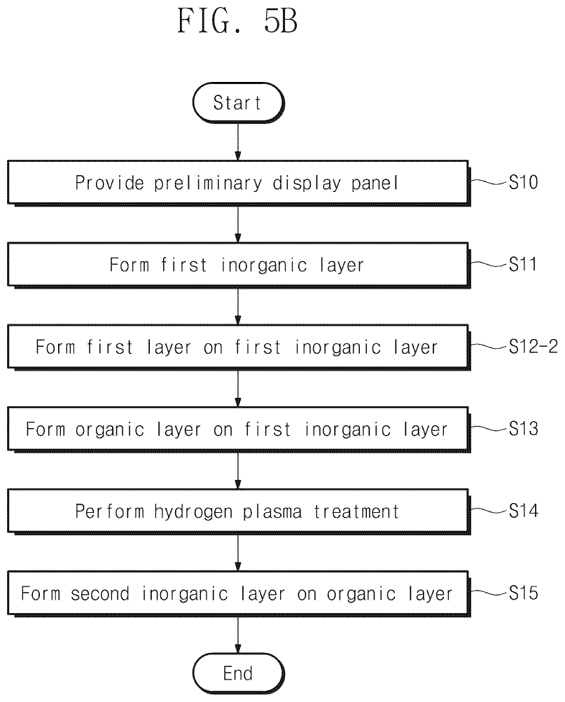

FIG. 5A is a flowchart of a method of manufacturing the display panel according to an embodiment of the present disclosure. FIG. 5B is a flowchart of a method of manufacturing the display panel according to an embodiment of the present disclosure.

Referring to FIG. 5A, the manufacturing method of the display panel may include providing a preliminary display panel (S10), forming a first inorganic layer (S11), plasma treating the first inorganic layer (S12-1), forming an organic layer on the first inorganic layer (S13), performing hydrogen plasma treatment (S14), and forming a second inorganic layer on the organic layer (S15).

The manufacturing method of the display panel shown in FIG. 5B may have the same or substantially the same processes as those of the manufacturing method of the display panel described above with reference to FIG. 5A, except the manufacturing method shown in FIG. 5B includes forming a first layer on the first inorganic layer (S12-2) as the process of pretreating the first inorganic layer.

The preliminary display panel provided in the providing of the preliminary display panel (S10) may correspond to the display panel before the first inorganic layer 41 (e.g., refer to FIG. 3) is formed. As an example, the preliminary display panel may include the insulating substrate 10, the circuit insulating layer 20, the display insulating layer 30, and the pixel PX, which are disposed under the first inorganic layer 41 as shown in FIG. 3, however, the components included in the preliminary display panel are not limited thereto or thereby. The processes of forming the components on the preliminary display panel to manufacture the display panel after the providing of the preliminary display panel (S10) will be described in more detail below hereinafter.

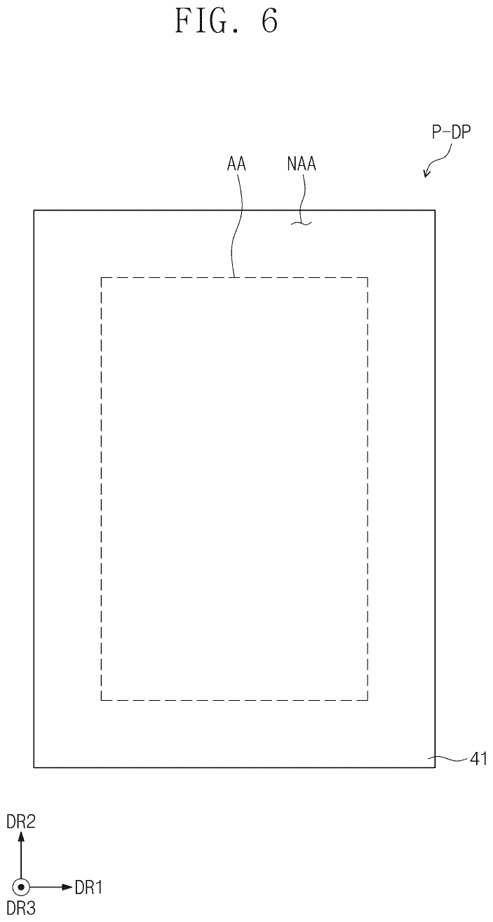

FIG. 6 is a plan view of a process of a manufacturing method of the display panel according to an embodiment of the present disclosure. FIG. 6 shows the forming of the first inorganic layer (S11) (e.g., refer to FIG. 5A).

Referring to FIG. 6, the first inorganic layer 41 may be formed on the preliminary display panel P-DP. The preliminary display panel P-DP may include a display area AA and a peripheral area NAA, which correspond to the display area AA and the peripheral area NAA of the display panel DP (e.g., refer to FIG. 3), respectively. The first inorganic layer 41 may be formed in an entire area of the display area AA. The first inorganic layer 41 may be formed in at least a portion of the peripheral area NAA. The first inorganic layer 41 may have an integral form overlapping with the display area AA and the peripheral area NAA.

The first inorganic layer 41 may be formed through a deposition process using a mask provided with a mask opening defined therethrough to correspond to an area where the first inorganic layer 41 is formed. As an example, the first inorganic layer 41 may be formed on the preliminary display panel P-DP using the mask provided with the mask opening defined therethrough to overlap with the display area AA and at least a portion of the peripheral area NAA.

The first inorganic layer 41 may have a single-layer structure of an inorganic layer, or a multi-layered structure of a plurality of inorganic layers. As an example, first inorganic layer 41 may include at least one of a lithium fluoride (LiF) layer, a silicon nitride (SiNx) layer, or a silicon oxynitride (SiOxNy) layer.

In the case where the first inorganic layer 41 includes a plurality of inorganic layers, the inorganic layers may be deposited using masks having the same mask opening, however, the present disclosure is not limited thereto or thereby.

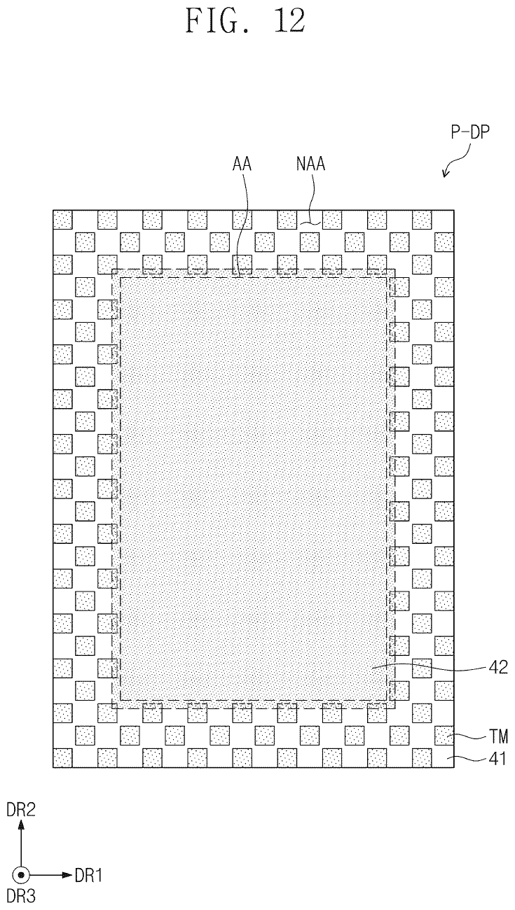

The upper surface of the first inorganic layer 41 may have a hydrophilicity through which an organic material is easily spread. As an example, an uppermost layer of the first inorganic layer 41 may be a silicon oxynitride (SiOxNy) layer having a high oxygen atom content. However, the material included in the first inorganic layer 41 is not particularly limited thereto, as long as a surface of the first inorganic layer 41 has the property of easily spreading the organic material. As the first inorganic layer 41 has the hydrophilicity, the organic layer 42 (e.g., refer to FIG. 12) to be formed on the first inorganic layer 41 may be easily spread on the first inorganic layer 41, may be tightly adhered to the first inorganic layer 41, and may not be easily separated from the first inorganic layer 41.

FIG. 7 is a perspective view of a process of the manufacturing method of the display panel according to an embodiment of the present disclosure. FIGS. 8A through 10B are views of masks MK according to various embodiments of the present disclosure.

FIG. 7 shows the pretreating of the first inorganic layer 41. The masks MK shown in FIGS. 8A to 10B may be used in the pretreating of the first inorganic layer 41.

According to one or more embodiments, the pretreating of the first inorganic layer 41 may be performed on a portion of the upper surface of the first inorganic layer 41 overlapping with the peripheral area NAA before the organic layer 42 (e.g., refer to FIG. 12) is formed on the first inorganic layer 41. In other words, the pretreating of the first inorganic layer 41 may be performed on the upper surface of the first inorganic layer 41 to prevent or substantially prevent the organic layer 42 (e.g., refer to FIG. 12) from being formed outside the peripheral area NAA due to the hydrophilicity of the upper surface of the first inorganic layer 41. As an example, the pretreating of the first inorganic layer 41 may include the plasma treating of the portion of the first inorganic layer 41 (e.g., S12-1, refer to FIG. 5A), or the forming of the first layer on the portion of the first inorganic layer 41 (e.g., S12-2, refer to FIG. 5B).

Referring to FIGS. 7, 8A, and 8B, the mask MK may be provided above the preliminary display panel P-DP in the pretreating of the first inorganic layer 41 through the plasma process, or in the pretreating of the first inorganic layer 41 by forming the first layer. The mask MK may include a first portion MA1 and a second portion MA2. Hereinafter, for convenience, the first portion MA1 and the second portion MA2 are described separately, however, they may correspond to parts of the mask MK that is provided in an integral form.

The first portion MA1 may overlap with the display area AA of the preliminary display panel P-DP. The first portion MA1 may entirely overlap with the display area AA, and according to an embodiment, the first portion MA1 may further overlap with a portion of the peripheral area NAA adjacent to the display area AA. In other words, the first portion MA1 may have a size equal to or greater than a size of the display area AA. The first portion MA1 may be a portion that is not opened, and may correspond to the display area AA in the mask MK. FIG. 7 shows the first portion MA1 having a quadrangular shape as a representative example, but the shape of the first portion MA1 may be variously modified to correspond to the display area AA of the preliminary display panel P-DP.

The second portion MA2 may be disposed adjacent to the first portion MA1. As an example, the second portion MA2 may surround (e.g., around a periphery of) the first portion MA1 when viewed in the plane (e.g., in a plan view). The second portion MA2 may overlap with the peripheral area NAA of the preliminary display panel P-DP. The second portion MA2 may have a size smaller than a size of the first portion MA1.

The second portion MA2 may include first blocking portions MC1 and first openings OP1. The first openings OP1 may be formed through (e.g., may penetrate) the second portion MA2. The first blocking portions MC1 may correspond to portions where the first openings OP1 are not defined in the second portion MA2.

The first blocking portions MC1 may be alternately arranged with the first openings OP1 in one direction (e.g., along one or more directions). As an example, the first blocking portions MC1 and the first openings OP1 may be alternately arranged with each other along the first direction DR1 and the second direction DR2.

The first blocking portions MC1 may be connected to each other to have an integral form. The first blocking portions MC1 may be connected to each other through a contact between at least portions of vertices or corners thereof. The first blocking portions MC1 connected to each other may surround (e.g., around peripheries of) the first openings OP1 when viewed in the plane (e.g., in a plan view). Accordingly, it may be possible to form the second portion MA2 having the integral shape without separated portions by forming the first openings OP1 alternately arranged with first blocking portions MC1.

The first blocking portions MC1, which are adjacent to the first portion MA1, from among the first blocking portions MC1 may extend from the first portion MA1. The first blocking portions MC1 adjacent to the first portion MA1 may be connected to one side of the first portion MA1 through their vertices or corners. Accordingly, it may be possible to form the mask MK having the integral shape without separated portions in the first portion MA1 and the second portion MA2.

The first openings OP1 may be uniformly or substantially uniformly arranged in the second portion MA2. As an example, distances between the first openings OP1 that are adjacent to each other may be the same or substantially the same as each other. The first openings OP1 may have the same or substantially the same size as each other. However, the arrangement and size of the first openings OP1 are not limited thereto or thereby, as long as the first openings OP1 are alternately arranged with the first blocking portions MC1 in the second portion MA2.

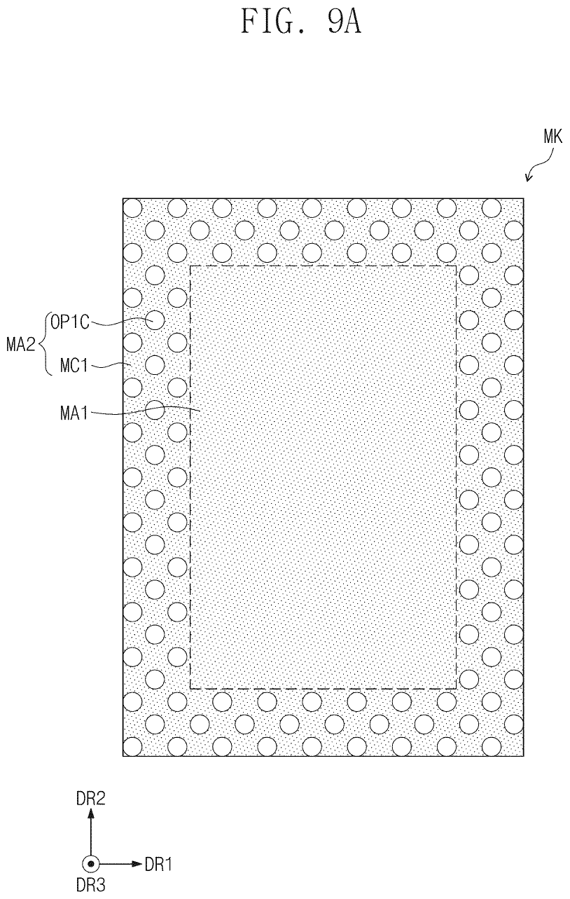

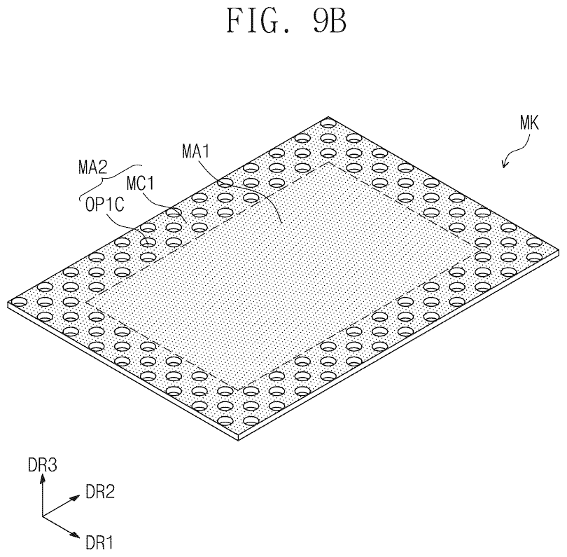

Each of the first openings OP1 may have a quadrangular shape when viewed in the plane (e.g., in a plan view), however, it is not limited thereto or thereby. Referring to FIGS. 9A and 9B, first openings OP1C may have a circular shape when viewed in the plane (e.g., in a plan view). The first openings OP1C having the circular shape may be alternately arranged with first blocking portions MC1 along the first direction DR1 and the second direction DR2. However, the shapes of the first openings OP1 and OP1C shown in FIGS. 8A to 9B are provided as examples, and the first openings OP1 and OP1C may have various suitable shapes, such as another polygonal shape or an oval shape, instead of the quadrangular shape or the circular shape. The shapes of the first openings OP1 and OP1C are not particularly limited, as long as the first openings OP1 and OP1C are alternately arranged with the first blocking portions MC1 in the second portion MA2.

Referring again to FIG. 7, the mask MK may define an area to be pretreated in the first inorganic layer 41. In other words, the first inorganic layer 41 may be pretreated in the area where the first openings OP1 are defined. The pretreatment area PTA (e.g., refer to FIG. 3) may be formed in the first inorganic layer 41 through the pretreatment process using the mask MK.

In the plasma treating of the first inorganic layer using the mask MK (e.g., S12-1, refer to FIG. 5A), an ionized gas may be supplied to the preliminary display panel P-DP from above the mask MK. The surface of the first inorganic layer 41 overlapping with the first openings OP1 may be plasma treated by the ionized gas passing through the first openings OP1. The plasma-treated surface of the first inorganic layer 41 may have a hydrophobicity. As an example, the first inorganic layer 41 may be pretreated through the plasma process using nitrogen (N2) gas. In this case, a nitrogen atom content may increase in the pretreated surface of the first inorganic layer 41 corresponding to first openings OP1, and the pretreated surface of the first inorganic layer 41 may have the hydrophobicity when compared with the surface of the first inorganic layer 41 corresponding to the first portion MA1. However, the kinds of the gas used in the plasma process are not limited thereto or thereby, as long as the surface of the first inorganic layer 41 corresponding to the first openings OP1 has the hydrophobicity. Because the pretreated first inorganic layer 41 has the hydrophobicity, the spreadability of the organic material may be controlled in the forming of the organic layer on the first inorganic layer 41 (e.g., S13, refer to FIG. 5A).

In the forming of the first layer on the first inorganic layer using the mask MK (e.g., S12-2, refer to FIG. 5B), a deposition material may be provided to the preliminary display panel P-DP from above the mask MK. As an example, the first layer may be deposited through a chemical vapor deposition (CVD) method using the mask MK. However, the deposition method for the first layer is not limited thereto or thereby. The deposition material may be deposited on the upper surface of the first inorganic layer 41 overlapping with the first openings OP1 after passing through the first openings OP1. In other words, the first layer may be formed on the upper surface of the first inorganic layer 41 overlapping with the first openings OP1. The first layer may be provided in a pattern corresponding to the first openings OP1.

The first layer may include a suitable material having the hydrophobicity. As an example, the first layer may include a suitable material with a higher nitrogen atom content than that of the upper surface of the first inorganic layer 41, such as silicon nitride. However, the material for the first layer is not particularly limited thereto, as long as the organic layer 42 (e.g., refer to FIG. 12) is not easily spread by the material for the first layer. As the first layer has the hydrophobicity, the spreadability of the organic material may be controlled in the forming of the organic layer on the first inorganic layer 41 (e.g., S13, refer to FIG. 5B).

As the first openings OP1 are alternately arranged with the first blocking portions MC1, the first portion MA1 may be provided integrally with the second portion MA2 without separated portions. Because one mask MK is aligned on the preliminary display panel P-DP, the first portion MA1 and the second portion MA2 may be aligned on the display area AA and the peripheral area NAA of the preliminary display panel P-DP, respectively. Portions of the first inorganic layer 41, which correspond to the first openings OP1 in the peripheral area NAA, may be pretreated through the pretreatment process using the mask MK. In addition, because the first portion MA1 is not opened, the surface of the first inorganic layer 41 corresponding to the first portion MA1 may not be pretreated. Accordingly, the surface of the first inorganic layer 41 corresponding to the display area AA may maintain or substantially maintain the hydrophilicity.

Referring to FIGS. 10A and 10B, openings may be further defined in the mask MK to correspond to areas defined in the preliminary display panel P-DP. As an example, the preliminary display panel P-DP may be provided with the module hole MH (e.g., refer to FIG. 2), and the hole area PA surrounding (e.g., around a periphery of) the module hole MH defined through the display panel DP as described above. Correspondingly, a mask hole HH and the second openings OP2 may be additionally defined in the first portion MA1 of the mask MK.

According to an embodiment, the first portion MA1 may include the mask hole HH, and the first area MAH1 surrounding (e.g., around a periphery of) the mask hole HH. The mask hole HH may overlap with the module hole MH (e.g., refer to FIG. 2) of the preliminary display panel P-DP. The number, location, and shape of the mask hole HH may be variously modified corresponding to the number, location, and shape of the module hole MH of the preliminary display panel P-DP. As an example, in a case where a plurality of module holes MH is defined through the preliminary display panel P-DP, the mask hole HH may be provided in a plurality, such that the mask holes HH respectively overlap with the module holes MH.

The first area MAH1 may overlap with the hole area PA (e.g., refer to FIG. 2) surrounding (e.g., around a periphery of) the module hole MH of the preliminary display panel P-DP. The number, location, and shape of the first area MAH1 may be variously modified corresponding to the number, location, and shape of the hole area PA (e.g., refer to FIG. 2) defined in the preliminary display panel P-DP. The first area MAH1 may include second blocking portions MC2 and the second openings OP2.

The second openings OP2 may be formed through (e.g., may penetrate) the first portion MA1 corresponding to the first area MAH1. The second openings OP2 may be arranged around the mask hole HH. However, the arrangement of the second openings OP2 is not limited to that shown in FIGS. 10A and 10B, and the second openings OP2 may be alternately arranged with the second blocking portions MC2 in one direction, like that of the first openings OP1 that are alternately arranged with the first blocking portions MC1.

The second openings OP2 may include two or more openings having different sizes from each other, however, they are not limited thereto or thereby. According to an embodiment, the second openings OP2 may have the same or substantially the same size as each other. As shown in FIG. 10A, each of the second openings OP2 may have a quadrangular shape when viewed in the plane (e.g., in a plan view), however, the present disclosure is not limited thereto or thereby. Each of the second openings OP2 may have a variety of suitable shapes, such as a polygonal shape, a circular shape, or an oval shape. The arrangement, size, and shape of the second openings OP2 are not particularly limited, as long as the second openings OP2 are arranged around the mask hole HH.

The second blocking portions MC2 may be connected to each other to have an integral form. The second blocking portions MC2 may be connected to each other through a contact between at least portions of vertices or corners thereof. The second blocking portions MC2 connected to each other may surround (e.g., around a periphery of) the second openings OP2 when viewed in the plane (e.g., in a plan view). The second blocking portions MC2 that are adjacent to an outer portion of the mask hole HH may be connected to the outer portion of the mask hole HH through the vertices or the corners thereof. The first portion MA1 of the mask MK may be formed in an integral shape without separated portions in the first area MAH1.

The first inorganic layer 41 of the preliminary display panel P-DP corresponding to the hole area PA (e.g., refer to FIG. 4) may be pretreated corresponding to the second openings OP2. In other words, the pretreatment area PTA (e.g., refer to FIG. 4) may be formed to correspond to the hole area PA in the first inorganic layer 41 through the pretreatment process of the first inorganic layer 41 using the mask MK of FIGS. 10A and 10B. A surface of a portion of the first inorganic layer 41 in an area overlapping with the hole area PA (e.g., refer to FIG. 4) and corresponding to the second openings OP2 may have a hydrophobicity, or a layer having a hydrophobicity in areas corresponding to the second openings OP2 may be formed on the first inorganic layer 41. Accordingly, the spread of the organic layer 42 in the hole area PA (e.g., refer to FIG. 4) may be controlled.

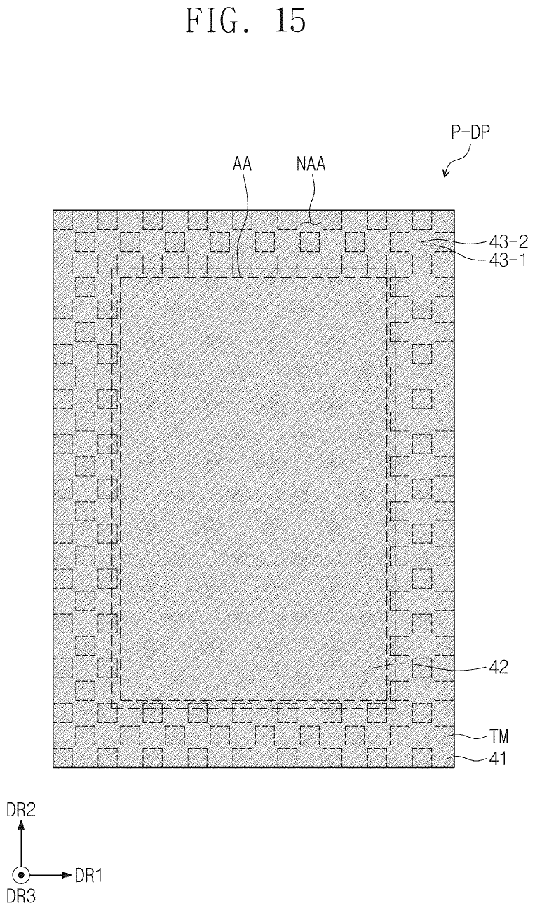

FIGS. 11 through 14 are plan views of various processes of the manufacturing method of the display panel according to one or more embodiments of the present disclosure. FIG. 15 is a plan view of a process of the manufacturing method of the display panel according to an embodiment of the present disclosure.

FIG. 11 shows the pretreated first inorganic layer 41 after the plasma treating of the first inorganic layer, or after the forming of the first layer on the first inorganic layer. The pretreatment portion TM may be formed in the pretreated first inorganic layer 41. An area of the first inorganic layer 41 in which the pretreatment portion TM is formed may correspond to the pretreatment area PTA (e.g., refer to FIG. 3).

Referring to FIG. 11, the pretreatment portion TM may be formed corresponding to the openings OP1 (e.g., refer to FIG. 7) of the mask MK. The pretreatment portion TM may have a higher hydrophobicity compared with that of the first inorganic layer 41 in the display area AA. As an example, the pretreatment portion TM may be a portion with a lower content of oxygen atoms or a higher content of nitrogen atoms than that of the first inorganic layer 41 in the display area AA. The pretreatment portion TM may correspond to a silicon nitride layer formed on the first inorganic layer 41. The pretreatment portion TM is not particularly limited thereto, as long as the pretreatment portion TM has a higher hydrophobicity compared with that of the first inorganic layer 41 corresponding to the display area AA.

Even though the pretreatment portion TM is not entirely formed on the first inorganic layer 41 overlapping with the peripheral area NAA, the continuity of the first inorganic layer 41 that is not pretreated may be blocked on the peripheral area NAA, because the area in which the pretreatment portion TM is formed and the area in which the pretreatment portion TM is not formed are alternately arranged with each other.

Accordingly, although the pretreatment area PTA (e.g., refer to FIG. 3) does not entirely include the pretreatment portion TM as the arrangement pattern of the pretreatment portion TM shown in FIG. 11, the first inorganic layer 41 corresponding to the pretreatment area PTA may have the hydrophobicity as a whole. Accordingly, the organic material may be prevented or substantially prevented from being spread to the outside of the peripheral area NAA.

FIG. 12 shows the forming of the organic layer 42 on the pretreated first inorganic layer 41 (e.g., S13, refer to FIG. 5A).

The organic layer 42 may include a monomer or a polymer. As an example, the organic layer 42 may include at least one of an acrylic resin, an epoxy resin, or silicon oxycarbide (SiOC), but the organic layer 42 is not limited thereto or thereby.

The organic layer 42 may be formed by coating an organic material using an inkjet method. The surface of the first inorganic layer 41 corresponding to the display area AA may not be pretreated due to the first portion MA1 (e.g., refer to FIG. 7) of the mask MK. Accordingly, the first inorganic layer 41 corresponding to the display area AA may have the hydrophilicity, and the organic material may be easily spread on the display area AA.

The surface of the first inorganic layer 41 corresponding to the peripheral area NAA may be pretreated through the first openings OP1 (e.g., refer to FIG. 7) of the mask MK, and thus, the pretreatment portion TM may be formed. The pretreatment portion TM may have the hydrophobicity, and may have a low affinity with the organic material coated on the first inorganic layer 41. The continuity of the first inorganic layer 41 having the hydrophilicity may be interrupted by the pretreatment portion TM on the peripheral area NAA, and the organic material may be prevented or substantially prevented from being spread to the outside of the area where the pretreatment portion TM is formed.

In other words, the portion of the first inorganic layer 41 corresponding to the display area AA may have the hydrophilicity, and the portion of the first inorganic layer 41 corresponding to the pretreatment area PTA (e.g., refer to FIG. 3) may have the hydrophobicity as a whole by the pretreatment portion TM. Accordingly, the area where the organic layer 42 is formed may be easily controlled by the pretreatment on the first inorganic layer 41, and thus, the reflow phenomenon of the organic material may be prevented or substantially prevented.

In a case where the organic layer 42 is formed without the pretreating of the first inorganic layer 41, the organic layer 42 may be easily spread on the peripheral area NAA by the first inorganic layer having the hydrophilicity. In this case, an ashing process may be used to remove a portion of the organic layer 42 formed in the peripheral area NAA. When the ashing process is performed on the organic layer 42, oxygen contained in the organic material may be gasified, and the electrodes E1 and E2 (e.g., refer to FIG. 3) of the light emitting element may be oxidized. According to one or more embodiments of the present disclosure, because the first inorganic layer 41 is pretreated, the reflow phenomenon of the organic material may be prevented or substantially prevented, and the ashing process of the organic layer 42 may be omitted. Therefore, the oxidation of the light emitting element, which may be caused by the ashing process, may be prevented or substantially prevented. In addition, costs and time used for the ashing process may be reduced or eliminated.

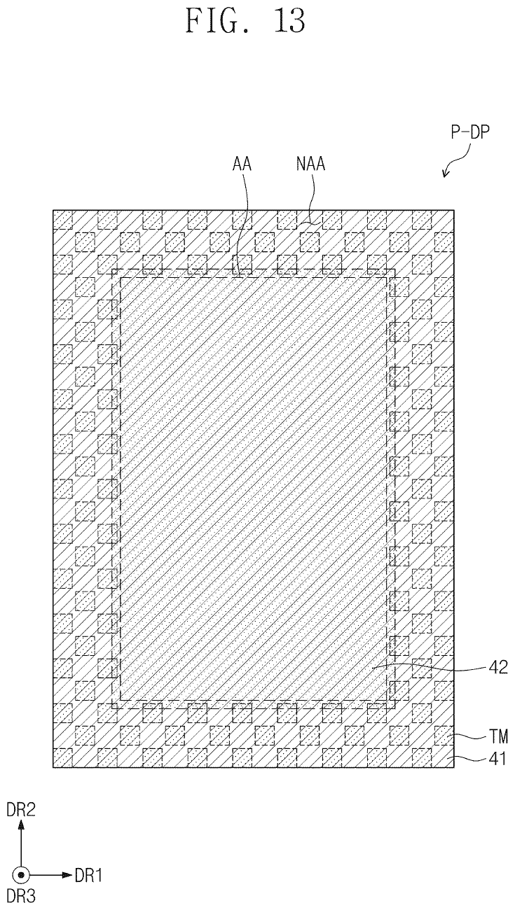

FIG. 13 shows the hydrogen plasma treating of the upper surface of the first inorganic layer 41 and the upper surface of the organic layer 42 (e.g., S14, refer to FIG. 5A). The surface of the first inorganic layer 41 and the organic layer 42 may be plasma treated under hydrogen gas or hydrogen ion conditions in the hydrogen plasma treating process. When the hydrogen plasma treatment is performed, the surface of the organic layer 42 and the first inorganic layer 41 may be modified, and an adhesive strength between the surface of the organic layer 42 and the second inorganic layer 43 and an adhesive strength between the surface of the first inorganic layer 41 and the second inorganic layer 43 may be improved.

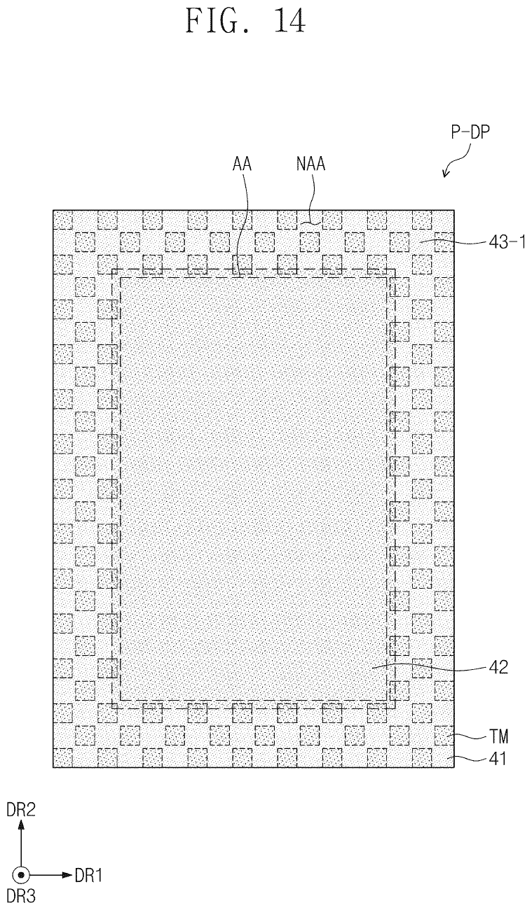

FIGS. 14 and 15 show the forming of the second inorganic layer 43 (e.g., refer to FIG. 3) on the organic layer 42 after the hydrogen plasma treatment (e.g., S15, refer to FIG. 5A). The second inorganic layer 43 (e.g., refer to FIG. 3) may be formed by depositing a plurality of sub-inorganic layers 43-1 and 43-2.

FIG. 14 shows a process of forming a first sub-inorganic layer 43-1 on the organic layer 42 using a first power. FIG. 15 shows a process of forming a second sub-inorganic layer 43-2 on the first sub-inorganic layer 43-1 using a second power.

Referring to FIG. 14, the first sub-inorganic layer 43-1 may be deposited on the display area AA and the peripheral area NAA. The first sub-inorganic layer 43-1 may be formed on the organic layer 42 using a mask provided with a mask opening defined (e.g., penetrating) therethrough to overlap with the display area AA and at least a portion of the peripheral area NAA. The first sub-inorganic layer 43-1 may be expanded to the peripheral area NAA where the organic layer 42 is not formed. Accordingly, the first sub-inorganic layer 43-1 may be in contact with the first inorganic layer 41 in the peripheral area NAA.

Referring to FIG. 15, the second sub-inorganic layer 43-2 may be deposited on the first sub-inorganic layer 43-1. The second sub-inorganic layer 43-2 may be deposited using the same mask as the mask used to deposit the first sub-inorganic layer 43-1, but the present disclosure is not limited thereto or thereby.

The first sub-inorganic layer 43-1 may be deposited under a lower power condition than that of the second sub-inorganic layer 43-2. In other words, the first power is lower than the second power. When a strong power is used immediately in an initial stage of forming the second inorganic layer 43, gas may be generated from the organic layer 42 under the second inorganic layer 43. However, when the low power is used as in the present embodiment, the gas may be prevented or substantially prevented from being generated in the organic layer 42 under the second inorganic layer 43, and reliability of the display device DD (e.g., refer to FIG. 1) may be improved.

Each of the first sub-inorganic layer 43-1 and the second sub-inorganic layer 43-2 may include an inorganic material, such as silicon nitride, aluminum oxide, silicon oxide, or the like. The first sub-inorganic layer 43-1 and the second sub-inorganic layer 43-2 may include the same material as each other, but may be formed under different power conditions from each other. However, the present disclosure is not limited thereto or thereby. According to an embodiment, the first sub-inorganic layer 43-1 and the second sub-inorganic layer 43-2 may include different materials from each other.

is not limited is not limited The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A mask comprising:
a first portion; and
a second portion surrounding the first portion, and having a size smaller than a size of the first portion in a plan view, the second portion comprising:
first blocking portions; and
first openings alternately located with the first blocking portions along one direction in a plan view.

2. The mask of claim 1, wherein the first portion comprises:
a mask hole; and
a first area surrounding the mask hole in a plan view, and comprising second openings located around the mask hole in a plan view.

3. The mask of claim 1, wherein each of the first openings has a polygonal shape.

4. The mask of claim 1, wherein each of the first openings has a circular shape.

5. The mask of claim 1, wherein the first openings have the same size as each other.

6. A method of manufacturing a display panel, comprising:
providing a preliminary display panel comprising a display area, a peripheral area adjacent to the display area, and a light emitting element located in the display area;
forming a first inorganic layer on the light emitting element to overlap with the display area and the peripheral area;
pretreating at least a portion of the first inorganic layer overlapping with the peripheral area through a plasma process using a first mask, the first mask comprising:
a first portion overlapping with the display area; and
a second portion spaced from the display area, and overlapping with the peripheral area, the second portion comprising:
first blocking portions; and
first openings alternately located with the first blocking portions along one direction in a plan view; and
forming an organic layer on the first inorganic layer.

7. The method of claim 6, wherein the first inorganic layer is formed on the light emitting element using a second mask comprising a mask opening overlapping with the display area and having a size greater than that of the first openings, and
wherein the first inorganic layer is deposited to correspond to the mask opening.

8. The method of claim 6, wherein a gas containing nitrogen is used in the plasma process.

9. The method of claim 6, wherein a surface of the first inorganic layer that is pretreated in areas overlapping with the first openings has a hydrophobicity higher than a hydrophobicity of the surface of the first inorganic layer overlapping with the first portion.

10. The method of claim 6, further comprising treating a surface of the organic layer through a plasma process using a hydrogen gas.

11. The method of claim 10, further comprising forming a second inorganic layer on the organic layer.

12. The method of claim 11, wherein the forming of the second inorganic layer comprises:
forming a first sub-inorganic layer using a first power; and
forming a second sub-inorganic layer on the first sub-inorganic layer using a second power higher than the first power.

13. The method of claim 6, wherein the preliminary display panel is further provided with a module hole defined therethrough to overlap with the display area, and a hole area defined therein to surround the module hole,
wherein the first portion is provided with a mask hole defined therethrough, and a first area surrounding the mask hole in a plan view, and
wherein the first area comprises second openings located around the mask hole in a plan view.

14. A method of manufacturing a display panel, comprising:
providing a preliminary display panel comprising a display area, a peripheral area adjacent to the display area, and a light emitting element located in the display area;
forming a first inorganic layer on the light emitting element to overlap with the display area and the peripheral area;
forming a first layer on the first inorganic layer overlapping with the peripheral area using a first mask to pretreat the first inorganic layer, the first mask comprising:
a first portion overlapping with the display area; and
a second portion spaced from the display area and overlapping with the peripheral area, the second portion comprising:
first blocking portions; and
first openings alternately located with the first blocking portions along one direction in a plan view; and
forming an organic layer on the first inorganic layer,
wherein the first layer is deposited corresponding to the first openings.

15. The method of claim 14, wherein a surface of the first layer has a nitrogen atom content higher than a nitrogen atom content of a surface of the first inorganic layer.

16. The method of claim 15, wherein the first layer comprises silicon nitride.

17. The method of claim 14, further comprising forming a second inorganic layer on the organic layer.

18. The method of claim 14, further comprising:
forming a first sub-inorganic layer on the organic layer using a first power; and
forming a second sub-inorganic layer on the first sub-inorganic layer using a second power higher than the first power.

19. The method of claim 14, wherein the first layer comprises a hydrophobic material.

20. The method of claim 14, wherein the preliminary display panel is further provided with a module hole defined therethrough to overlap with the display area, and a hole area defined therein to surround the module hole,
wherein the first portion is provided with a mask hole defined therethrough, and a first area surrounding the mask hole in a plan view, and
wherein the first area comprises second blocking portions, and second openings alternately located with the second blocking portions along one direction in a plan view.
